(19) United States
(12) Patent Application Publication
(10) Pub. No.: US 2025/0046655 A1
(43) Pub. Date: Feb. 6, 2025

(54) MODIFYING TSV LAYOUT AND THE STRUCTURES THEREOF

(71) Applicant: Taiwan Semiconductor Manufacturing Co. Ltd., Hsinchu (TW)

(72) Inventors: Chao Yi Lin, Kaohsiung City (TW); Kuo-Yen Liu, Hsinchu (TW); Chih-Hsiang Yao, Hsinchu (TW)

(21) Appl. No.: 18/524,386

(22) Filed: Nov. 30, 2023

Related U.S. Application Data
(60) Provisional application No. 63/517,377, filed on Aug. 3, 2023.

(51) Int. Cl. H01L 21/768; G06F 30/392; H01L 23/58

(52) U.S. Cl. CPC H01L 21/76898; G06F 30/392; H01L 23/585

(57) ABSTRACT

A method includes finding a first plurality of through-silicon vias from a first layout of a wafer, and finding a second plurality of through-silicon vias from the first plurality of through-silicon vias. The second plurality of through-silicon vias are connected in parallel. The second plurality of through-silicon vias are merged into a large through-silicon via to generate a second layout of the wafer.

### PRIORITY CLAIM AND CROSS-REFERENCE

This application claims the benefit of the following provisionally filed U.S. Patent application: Application No. 63/517,377, filed on Aug. 3, 2023, and entitled “PRELIMINARY MODIFICATION OF TSV LAYOUT AND RESULTED SEMICONDUCTOR STRUCTURE,” which application is hereby incorporated herein by reference.

### BACKGROUND

Through-Silicon Vias (TSVs) are used as electrical paths in device dies, so that the conductive features on opposite sides of the device dies may be interconnected. The formation process of a TSV may include etching a semiconductor substrate to form an opening, filling the opening with a conductive material to form the TSV, performing a backside grinding process to remove a portion of the semiconductor substrate from backside and to reveal the TSV, and forming an electrical connector on the backside of the semiconductor substrate to connect to the TSV.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a device die including through-silicon vias (TSVs) in accordance with some embodiments.

FIG. 1B illustrates a cross-sectional view of a device die including merged through-silicon vias (TSVs) in accordance with some embodiments.

FIGS. 2A, 2B, and 2C illustrate a process for merging TSV cells in accordance with some embodiments.

FIGS. 3A, 3B, 3C, 3D, and 3E illustrate the filtering of TSVs for merging in accordance with some embodiments.

FIGS. 4A and 4B illustrate some TSVs to be merged and some TSVs not to be merged in accordance with some embodiments.

FIG. 5 illustrates the merged and unmerged TSVs in accordance with some embodiments.

FIGS. 6A, 6B, 6C, 6D, 6E. 6F, 6G, and 6H illustrate the filtering of TSVs for merging and some merged TSVs in accordance with some embodiments.

FIGS. 7A and 7B illustrate a top view and a cross-sectional view, respectively, of merged TSVs and the corresponding packages in accordance with some embodiments.

FIGS. 8-10 illustrate the formation of TSVs through a via-first process in accordance with some embodiments.

FIGS. 11-13 illustrate the formation of TSVs through a via-middle process in accordance with some embodiments.

FIGS. 14-16 illustrate the formation of TSVs through a via-last process in accordance with some embodiments.

FIGS. 17-21 illustrate the views of packages that may adopt merged TSVs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of determining and merging Through-Silicon Vias (TSVs) and the resulting structure are provided. In accordance with some embodiments of the present disclosure, a first layout of a wafer including the layout of TSVs is provided. The TSVs that meet certain pre-determined criteria are determined. The determined TSVs are then merged to form a second layout of the wafer including large merged TSVs. The wafer including large TSVs are then manufactured. By merging TSVs, the resistance of the TSVs is reduced without violating design rules and without costing larger chip areas. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

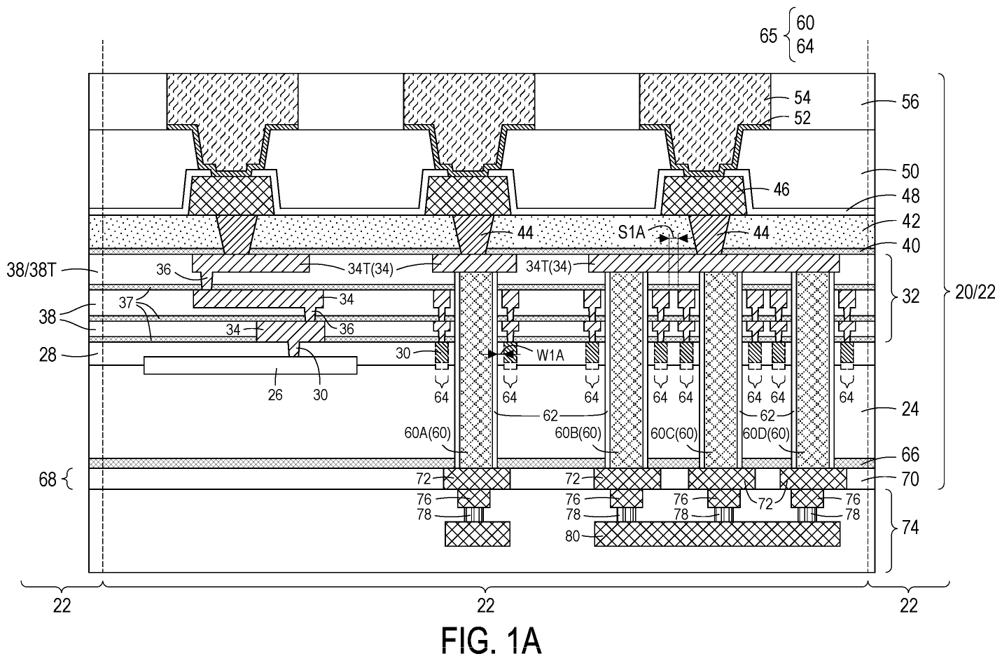

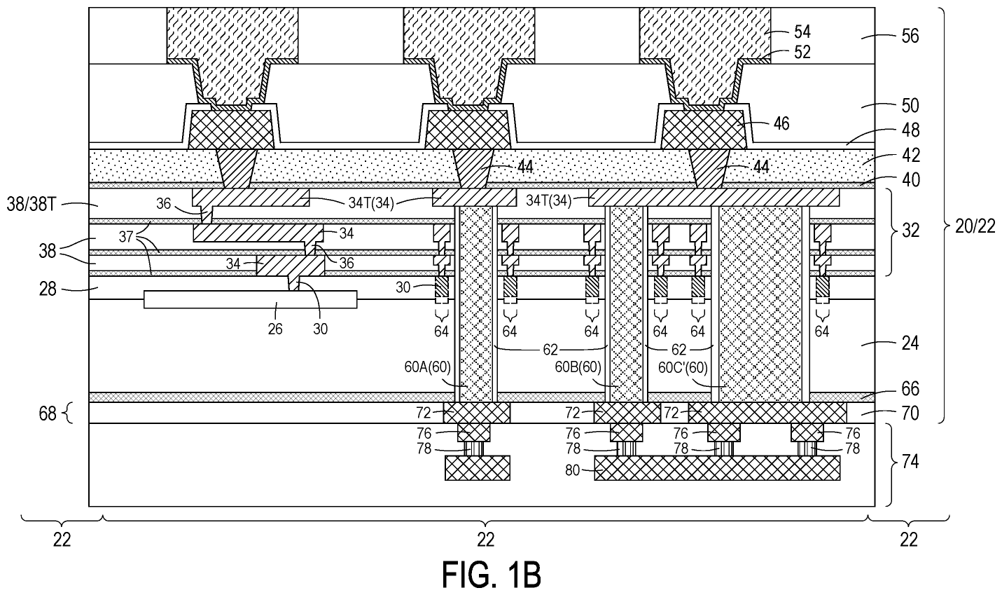

FIG. 1A illustrates a cross-sectional view of wafer 20. It is appreciated that the wafer 20 as shown in FIG. 1A may be manufactured as physical entities. Accordingly, the wafer 20 and the features therein discussed referred to FIG. 1A may be both of the layout and the manufactured physical entities. Alternatively, wafer 20 is laid out, but is not manufactured as physical entities. Accordingly, the wafer 20 and the features in wafer 20 discussed hereinafter may be the layout of the wafer 20, but not a physical wafer.

The layout of TSVs and/or TSV cells in the wafer 20 as shown in FIG. 1A is modified, and the resulting modified layout is implemented through manufacture as physical entities and in physical wafers. The resulting wafer 20 manufactured from the modified layout is illustrated in FIG. 1B. Accordingly, the wafer 20 and the features therein discussed referred to FIG. 1B may be both of the layout and the manufactured physical entities.

In accordance with some embodiments of the present disclosure, wafer 20 is or comprises a device wafer including active devices and possibly passive devices, which are represented as integrated circuit devices 26. Wafer 20 may include a plurality of chips/dies 22 therein, with one of chips 22 being illustrated. In accordance with alternative embodiments of the present disclosure, wafer 20 is an interposer wafer, which is free from active devices, and may or may not include passive devices.

In accordance with some embodiments of the present disclosure, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Shallow Trench Isolation (STI) regions (not shown) may be formed in semiconductor substrate 24 to isolate the active regions in semiconductor substrate 24.

In accordance with some embodiments of the present disclosure, wafer 20 includes integrated circuit devices 26, which are formed on the top surface of semiconductor substrate 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein. In accordance with alternative embodiments, wafer 20 is used for forming interposers (which are free from active devices).

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 28 may be formed using spin-on coating, Flowable Chemical Vapor Deposition (FCVD), or the like. In accordance with some embodiments of the present disclosure, ILD 28 may also be formed using a deposition method such as Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments of the present disclosure, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Interconnect structure 32 is formed over ILD 28 and contact plugs 30. Interconnect structure 32 includes metal lines 34 and vias 36, which are formed in dielectric layers 38 (also referred to as Inter-metal Dielectrics (IMDs)) and etch stop layers 37. The metal lines at a same level are collectively referred to as a metal layer hereinafter. In accordance with some embodiments of the present disclosure, interconnect structure 32 includes a plurality of metal layers including metal lines 34 that are interconnected through vias 36. Metal lines 34 and vias 36 may be formed of copper or copper alloys, and can also be formed of other metals.

In accordance with some embodiments of the present disclosure, dielectric layers 38 are formed of low-k dielectric materials. The dielectric constants (k values) of the low-k dielectric materials may be lower than about 3.5, for example. Dielectric layers 38 may comprise a carbon-containing low-k dielectric material, Hydrogen SilsesQuioxane (HSQ), MethylSilsesQuioxane (MSQ), or the like. Etch stop layers 37 are formed underlying the respective dielectric layers 38, and may be formed of or comprise aluminum nitride, aluminum oxide, silicon oxycarbide, silicon nitride, silicon carbide, silicon oxynitride, or the like, or multi-layers thereof.

The formation of metal lines 34 and vias 36 in dielectric layers 38 may include single damascene processes and/or dual damascene processes. In a single damascene process for forming a metal line or a via, a trench or a via opening is first formed in one of dielectric layers 38, followed by filling the trench or the via opening with a conductive material. A planarization process such as a CMP process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

Metal lines 34 include top conductive (metal) features such as metal lines, metal pads, or vias (denoted as 34T) in a top dielectric layer (denoted as dielectric layer 38T), which is the top layer of dielectric layers 38. In accordance with some embodiments, dielectric layer 38T is formed of a low-k dielectric material similar to the material of lower ones of dielectric layers 38. The metal features 34T in the top dielectric layer 38T may also be formed of copper or a copper alloy, and may have a dual damascene structure or a single damascene structure.

In accordance with some embodiments, etch stop layer 40 is deposited on the top dielectric layer 38T and the top metal layer. Etch stop layer 40 may be formed of or comprise silicon nitride, silicon oxide, silicon oxycarbide, silicon oxynitride, or the like.

Passivation layer 42 (sometimes referred to as passivation-1 or pass-1) is formed over etch stop layer 40. In accordance with some embodiments, passivation layer 42 is formed of a non-low-k dielectric material having a dielectric constant equal to or greater than about the dielectric constant of silicon oxide. Passivation layer 42 may be formed of or comprise an inorganic dielectric material, which may include a material selected from, and is not limited to, Undoped Silicate Glass (USG), silicon nitride (SiN), silicon oxide (SiO₂), silicon oxy-nitride (SiON), silicon oxy-carbide (SiOC), or the like, combinations thereof, and/or multi-layers thereof. In accordance with some embodiments, the top surfaces of top dielectric layer 38T and metal lines 34 are level with one another. Accordingly, passivation layer 42 may be a planar layer.

In accordance with some embodiments, vias 44 are formed in passivation layer 42 and etch stop layer to electrically connect to the underlying top metal features 34T. Metal pads 46 are further formed over vias 44. In accordance with some embodiments, metal pads 46 comprise aluminum, aluminum copper, or the like. Passivation layer 48 (sometimes referred to as passivation-2 or pass-2) is also formed, and may extend on the sidewalls and the top surfaces of metal pads 46. Passivation layer 48 may be formed of or comprises silicon oxide, silicon nitride, or the like, or multi-layers thereof.

In accordance with some embodiments, dielectric layer 50 is formed, for example, by dispensing a polymer in a flowable form, and then curing polymer layer 50. Dielectric layer layer 50 is patterned to expose metal pads 46. Dielectric layer 50, when formed of polymer, may be formed of or comprise polyimide, polybenzoxazole (PBO), or the like. Alternatively, dielectric layer 50 may be formed of or comprise an in organic dielectric material such as silicon oxide, silicon nitride, silicon oxynitride, or the like.

Under-Bump-Metallurgies (UBMs) 52 and bond pads 54 are then formed to electrically connect to the underlying metal pads 46. The formation processes of UBMs 52 and bond pads 54 may include depositing a blanket metal seed layer extending into the openings in passivation layer 48 and polymer layer 50, forming a patterned plating mask on the metal seed layer, plating bond pads 54, removing the plating mask, and etching the portions of the blanket metal seed layer previously covered by the plating mask. In accordance with some embodiments, dielectric layer 56 is formed to have a top surface coplanar with the top surfaces of bond pads 54, and may be used for hybrid bonding.

TSVs 60 (including TSV 60A, 60B, 60C, and 60D) are formed to penetrate through semiconductor substrate 24. Each of the TSVs 60 is surrounded by a dielectric isolation layer 62, which electrically decouple the corresponding TSVs 60 from semiconductor substrate 24. In the following discussed example embodiments, it is assumed that TSVs 60 extend to the bottom surfaces of top metal features 34T. In accordance with alternative embodiments, TSVs 60 may extend to any level including the top surface of semiconductor substrate 24, the top surface of ILD 28, the top surface of any of the dielectric layers 38, or a higher level higher than the top dielectric layer 38T.

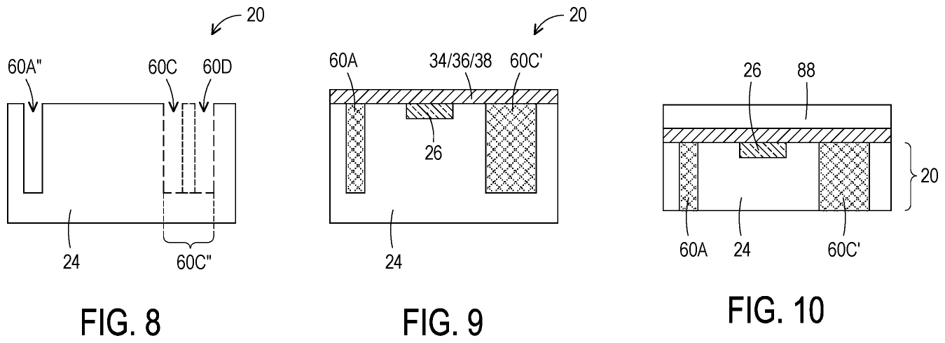

Although not illustrated, TSVs 60 may be tapered, with either the top width greater than the respective bottom width, or the bottom width greater than the respective top width, depending on wither the TSVs 60 are formed through a via-first process, a via-middle process, or a via-last process, as will be discussed referring to FIGS. 8 through 16.

On the back of semiconductor substrate 24, backside redistribution structure 68 is formed. Backside redistribution structure 68 includes dielectric layer 70 and Redistribution lines (RDLs) 72 in accordance with some embodiments. RDLs 72 may include bond pads, which are also referred to as bond pads 72. Although one RDL layer is illustrated, backside redistribution structure 68 may include more RDL layers.

FIG. 1A further includes package component 74 bonding to device die 22 in accordance with some embodiments. Package component 74 may be a device die (which may be a discrete device die already sawed from a wafer), or may be a part of an un-sawed wafer that includes a plurality of device dies. Package component 74 may include bond pads 76 bonding to bond pads 72, and vias 78 connected to bond pads 76.

In accordance with some embodiments, TSV 60A is a single TSV, which is not connected in parallel with any other TSV 60. TSV 60A may be used for conducting signals. TSVs 60B, 60C, and 60D are in a multi-TSV group, which, when packaged and at a time the respective package is powered up, are connected in parallel and conduct the same voltage and/or same signals. In accordance with some embodiments, the top ends of the TSVs 60B, 60C, and 60D are physically joined to a same top metal feature (pad) 34T, and hence the top ends are also electrically interconnected. In accordance with alternative embodiments, the top ends of the TSVs 60B, 60C, and 60D are physically joined to different overlying metal features, and are eventually interconnected by another overlying metal feature. In accordance with some embodiments, TSVs 60B, 60C, and 60D are used to conduct power such as VDD, electrical ground, or the like, which may be related to large currents.

In accordance with some embodiments, as illustrated, the bottom ends of the TSVs 60B, 60C, and 60D are physically joined to different bond pads 72, but are electrically interconnected through a same metal pad 80, which is in package component 74, rather than in device die 22. In accordance with some embodiments, the bond pad electrically interconnecting TSVs 60B, 60C, and 60D may also be the backside interconnect structure 68 of wafer 20.

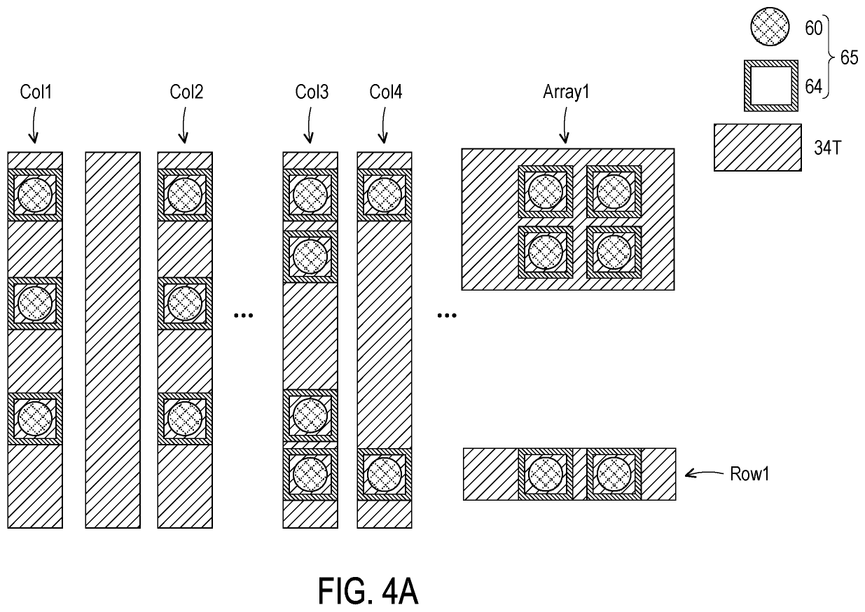

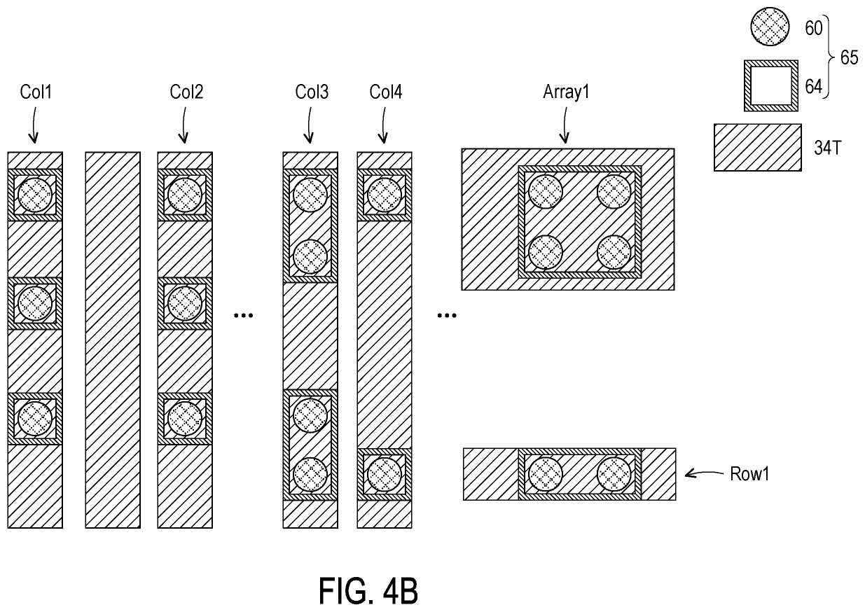

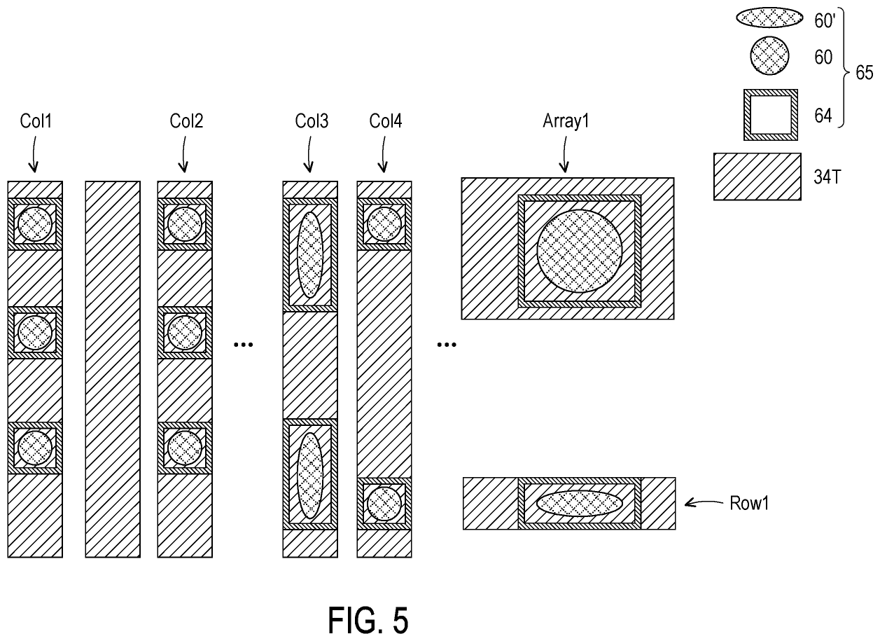

In accordance with some embodiments, each of the TSVs 60A, 60B, 60C, and 60D is surrounded by a guard ring 64, which fully encircle the corresponding TSV 60 when viewed from top. In accordance with some embodiments, each guard ring 64 includes a metal ring in each of the metal layer and via layer into which it extends. The metal rings in the plurality of via layers and a plurality of metal layers are interconnected to form a solid metal ring. Throughout the description, a guard ring 64 and the TSV encircled by the guard ring 64 are collectively referred to as a TSV cell 65, and example TSV cells 65 are illustrated in FIGS. 4A, 4B, and 5.

In accordance with some embodiments, the topmost ends of the guard rings 64 are in a metal layer that is lower than top end of the TSVs 60. For example, when TSVs 60 extend to the bottom of the top metal layer as illustrated, guard rings 64 include portions in the metal layer immediately under the top metal layer, and in the metal layers below. In accordance with some embodiments, guard rings 64 include contact plug portions in ILD 28 and at the same level as contact plugs 30. There may be, or may not be, metal silicide ring lower than the contact plug portion of the guard rings 64. In accordance with alternative embodiments, guard rings 64 have the bottommost surface higher than ILD 28. Guard rings 64 may be electrically grounded.

The region separating each guard ring 64 from the corresponding encircled TSV 60 is referred to as a first buffer zone. Neighboring guard ring 64 is also separated from each other by a second buffer zone. The widths WiA of the first buffer zones and the spacing S1A of the second buffer zones need to be greater than certain critical values, so that the problems such as electrical shorting will not occur. Reserving buffer zones causes the chip area available to the TSVs 60 to be limited, and it is difficult to form large TSVs. The resistance of the TSVs is thus difficult to reduce due to the difficulty in increasing the lateral dimensions of the TSVs.

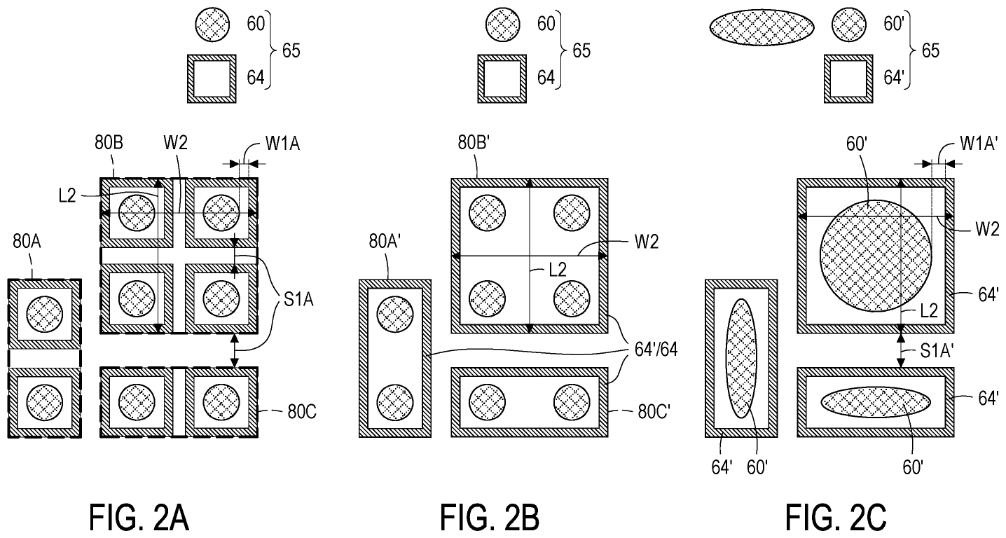

FIGS. 2A, 2B, and 2C illustrate the intermediate stages in filtering the TSV cells, finding candidate TSV cells that meet certain criteria, and redesigning the layout of the TSVs that are found, so that the top-view areas of the resulting TSVs in the candidate TSV cells are increased, without requiring larger chip areas. The TSV cells shown in FIGS. 2A, 2B, and 2C are the candidate TSV cells that will be merged. The features are marked using legend.

Referring to FIG. 2A, a plurality of TSV cell groups 80A, 80B, and 80C are illustrated. The TSV cell groups may be in the layout of the structure in FIG. 1A. Each of the cell groups 80A, 80B, and 80C includes an array of TSV cells 65. Cell groups 80A, 80B, and 80C include a 2×1 array (with two rows and one column), a 2×2 array (with two rows and two columns), and a 1×2 array (with one row and two columns).

FIG. 2B illustrates TSV cells 80A′, 80B′, and 80C′, each including a guard ring 64 and a plurality of TSVs 60 therein. Similarly, TSV cells 80A′, 80B′, and 80C′ include a 1×2 array, a 2×2 array, and a 2×1 array of TSVs 60. FIG. 2B may also be an intermediate stage in the redesigning of the layout of the layout in FIG. 2A, wherein the individual guard rings in the same cell group 80A′, 80B′, or 80C′ are removed, and are replaced with a merged large guard ring 64′ that encircles all of the TSVs 60 whose guard rings have been removed.

FIG. 2C illustrates the merged TSVs 60′ in accordance with some embodiments. The merged TSVs 60′ also have the first buffer zone between TSVs 60′ and their corresponding surrounding guard rings 64′ and second buffer zone between neighboring guard rings 64′. In accordance with some embodiments, width W1A′ of the first buffer zone is equal to or greater than the width WiA (FIG. 2A) of the first buffer zone. Width S1A′ of the second buffer zone may also be equal to or greater than the spacing S1A (FIG. 2A) of the second buffer zone.

In accordance with some embodiments, when modifying the layout of TSVs, the chip area occupied by the TSVs is not modified. For example, the contour width W2 (FIG. 2A) of TSV cells 65 to be merged may be equal to or smaller than the widths W2 in FIGS. 2B and 2C, the contour length L2 (FIG. 2A) of TSV cells 65 to be merged may be equal to or smaller than the lengths L2 in FIGS. 2B and 2C. Keeping the areas and the dimension of the TSVs unchanged or smaller has the advantageous of not requiring the layout change of their surrounding features, their overlying features, and their underlying features. This will significantly reduce the effort of redesign.

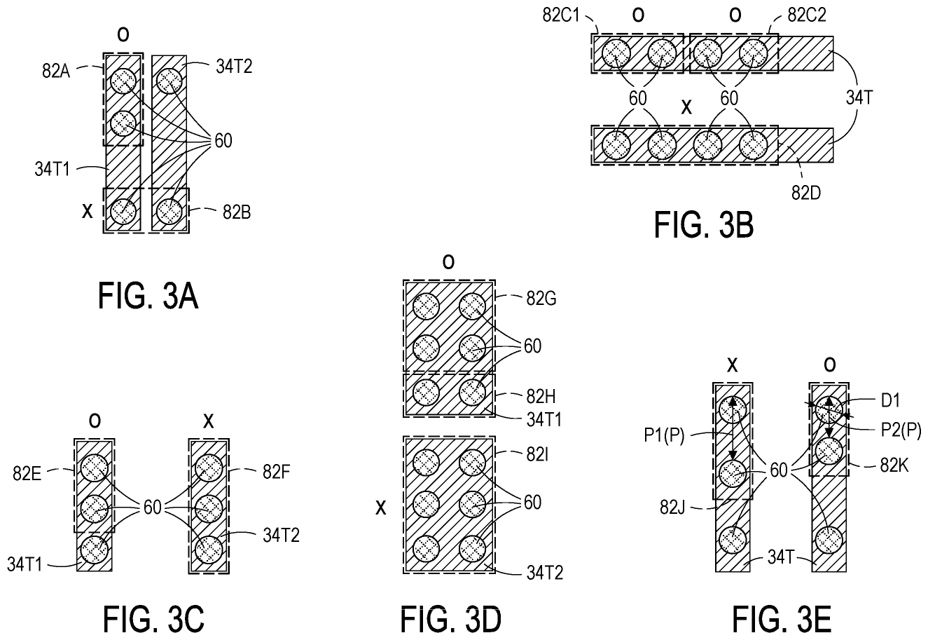

FIGS. 3A, 3B, 3C, 3D, and 3E illustrate some examples showing the criteria for finding (determining) the candidate TSV cells to be merged in accordance with some embodiments. Some TSVs are grouped and illustrated as encircled by dashed frames, and an “0” sign may be placed close the dashed frame to indicate that the TSVs in the respective frame can be merged. An “X” sign may be placed close the dashed frame to indicate that the TSVs in the respective frame cannot be merged. Although not illustrated, each of the TSVs 60 in these features may be encircled by a guard ring. Accordingly, the illustrated TSVs 60 represent the corresponding TSV cells 65.

The TSV cells that are to be merged are connected in parallel, and hence always have the same voltage. For example, as shown in FIG. 3A, the two TSV cells in dashed frame 82A are connected to the same metal feature 34T1 may be merged, while the two TSV cells in dashed frame 82B are connected to two different metal features 34T1 and 34T2 that are electrically decoupled and may carry different voltages. Accordingly, the two TSV cells in dashed frame 82B will not be merged.

The TSVs to be merged cannot expand for a too-long distance. In accordance with some embodiments, for an array of TSVs to be merged, the count of the TSVs in a row and a column is equal to or smaller than a critical count. In accordance with some embodiments, the critical count is 2, and hence the TSVs forming a 1×2 array, a 2×2 array, and a 2×1 array may be merged, while the TSVs in larger TSV arrays may not be merged. The critical count may also be slightly greater than 2, such as equal to 3 in accordance with alternative embodiments. In FIGS. 3B, when the critical count is equal to 2, the two TSVs in dashed frame 82C1 may be merged, the two TSVs in dashed frame 82C2 may be merged, while the fourth TSVs in dashed frame 82D will not merged into one TSV, although they may be merged as two large TSVs. Maintaining the critical count will ensure that the merged TSVs will not have a too-large area, which may cause problems due to too-severe pattern loading effect.

FIG. 3C illustrates an example wherein three TSVs 60 are connected to the same metal feature 34T1. In accordance with some embodiments, the two TSVs in dashed frame 82E are to be merged, while the TSV 60 outside of dashed frame 82E is left unmerged. As also shown in FIG. 3C, three TSVs 60 are connected to the same metal feature 34T2 and are denoted by dashed frame 82F. In accordance with some embodiments in which the critical count is 2, these three TSVs will not be merged as a single large TSV, and may stay as discrete TSVs.

FIG. 3D illustrates six TSVs 60 are connected to the same metal feature 34T1. In accordance with some embodiments, the six TSVs 60 are divided into a 2×2 array (shown in dashed frame 82G), and a 1×2 array (shown in dashed frame 82H). The four TSVs 60 in the same dashed frame 82G may be merged together to form a large TSV, and the two TSVs 60 in the same dashed frame 82H may be merged together to form a large TSV. As also shown in FIG. 3D, another six TSVs 60 are connected to the same metal feature 34T2. The six TSVs 60 in the same dashed frame 82I will not be all merged together. These TSVs 60 may, however, be merged like the TSVs in dashed frames 82G and 82H, or may remain as discrete TSVs.

FIG. 3E illustrates some embodiments in which the spacing between some TSVs are too large, and are greater than a pre-determined threshold value. In accordance with some embodiments, assuming the diameter (or lateral width or length if the TSV is not round) of TSVs 60 are equal to D1, and the pitch of neighboring TSVs 60 is equal to P, when the ratio P/D1 of the pitch P is greater than a critical ratio, the TSVs 60 will not be merged. Otherwise, the TSVs 60 can be merged. In accordance with some embodiments, the critical value of the ratio P/D1 is equal to about 2 (or may be set to a value greater than 1 and smaller than 2). In the example shown in FIG. 3E, assuming the ratio P1/D1 is greater than the critical ratio, and the ratio P2/D1 is smaller than the critical ratio, the TSVs 60 in the dashed frame 82J will not be merged, and the TSVs 60 in the dashed frame 82K will be merged.

In addition to the criteria discussed referring to FIGS. 3A, 3B, 3C, 3D, and 3E, the TSVs to be merged will not have other conductive features between the them and at the same levels as them.

In addition, the priority of merging may be determined, and the merging may be performed based on the priority. For example, if merging more TSVs has the highest priority, then as shown in FIG. 3D, the four TSVs in the dashed frame 82G are merged into one large TSV, and the remaining two TSVs in dashed frame 82H are merged into one large TSV.

If, however, merging horizontally located TSVs has the highest priority, the two top TSVs in dashed frame 82G are merged into one large TSV, and the two bottom TSVs in dashed frame 82G are merged into one large TSV. The two TSVs in dashed frame 82H are also merged into one large TSV.

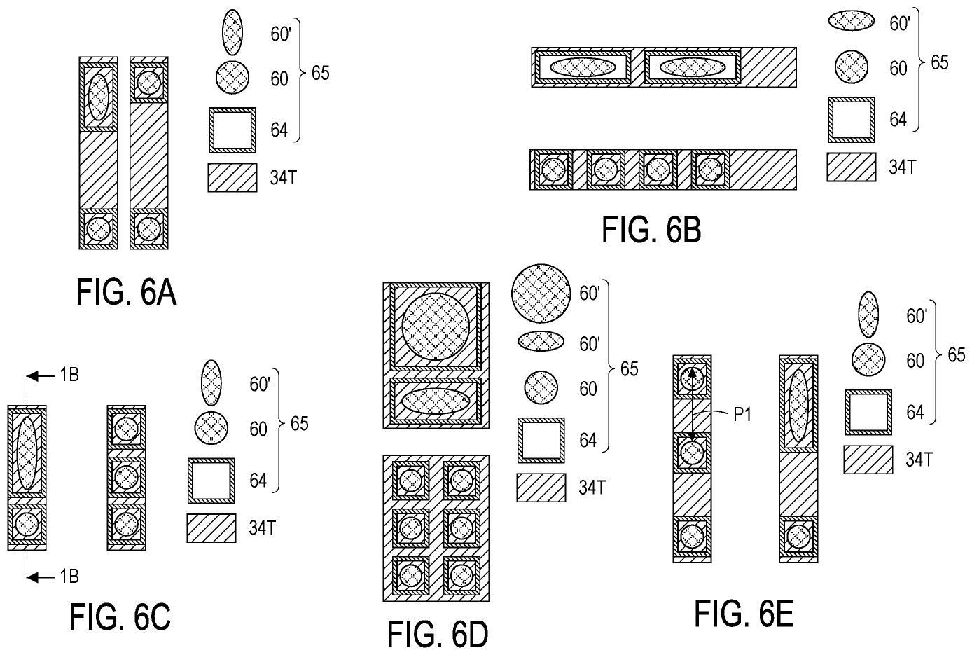

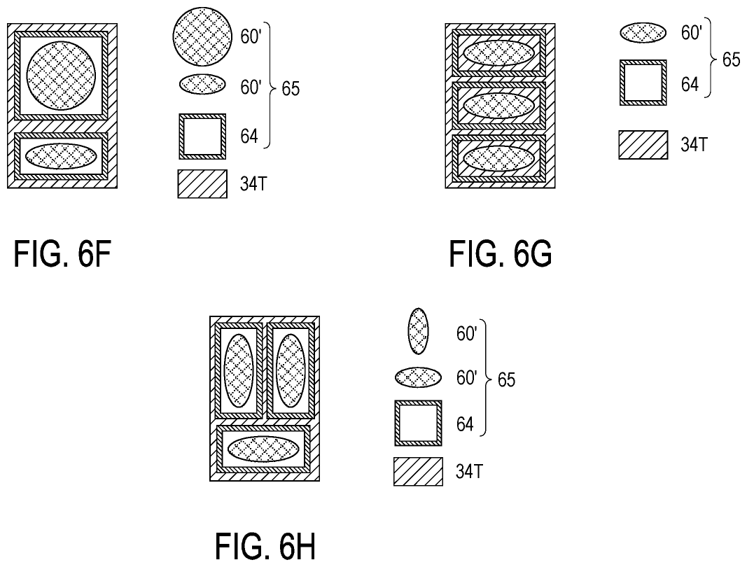

When merging vertically located TSVs has the highest priority, the two left TSVs in dashed frame 82G are merged into one large TSV, and the two right TSVs in dashed frame 82G are merged into one large TSV. The two TSVs in dashed frame 82H are also merged into one large TSV. The examples different types of priorities and the respective merged TSVs are shown in FIGS. 6F, 6G, and 6H as examples, as will be discussed subsequently.

FIGS. 4A, 4B, and 5 illustrate the TSVs (and TSV cells) to be merged, and the resulting merged TSVs and TSV cells in accordance with some embodiments. The features are marked using legend. Referring to FIG. 4A, a plurality of TSVs 60 (marked using legend), guard rings 64, and the corresponding metal feature 34T are illustrated. The first column Col1 of TSV cells 65 is spaced apart from the second column Col2 of TSV cells 65 by a metal feature 34T. The third column Col3 of TSV cells 65 are divided into two groups, with each of the groups of TSV cells 65 being closely located with the corresponding pitch-to-diameter P/D ratio smaller than the critical ratio. The TSV cells 65 in the neighboring groups have a pitch-to-diameter P/D ratio greater than the critical ratio. The fourth column Col4 of TSV cells 65 are spaced apart far, with the corresponding pitch-to-diameter P/D ratio being greater than the critical ratio. Another four TSV cells 65 are arranged as an array array1, and are closely located. Yet another two TSV cells 65 are closely located to each other and forming row1.

FIG. 4B illustrates an alternative layout, in which the closely located TSVs 60 are encircled by the same guard ring 64. This layout may also be the modified intermediate layout that is modified from the layout in FIG. 4A.

FIG. 4C illustrates the layout modified from the layout illustrated in FIGS. 4A and/or 4B, wherein TSVs 60 are merged into large TSVs, and the guard rings 64 may also be merged. In accordance with some embodiments, the 2×2 TSVs are merged as a large round TSV. The 1×2 TSVs and the 2×1 TSVs are merged as oval TSVs, so that their sizes are increased, while the width of the resulting buffer zones may maintain.

FIG. 1B illustrates a cross-sectional view of wafer 20 and device die 22 as manufactured, with the modified layout including merged TSVs and merged TSV cells incorporated. As shown in FIG. 1B, the layout of the TSVs 60C and 60D as shown in FIG. 1A are modified, and are merged to form large TSV 60C′ as shown in FIG. 1B. In the example structure as shown in FIG. 1B, TSVs 60A and 60B are not merged, and may have round top-view shapes. The top-view shape of TSV 60C′ may be oval, as illustrated in FIG. 5. The layout of the TSVs 60B and 60C′ as in FIG. 1B may be obtained from the cross-section 1B-1B in FIG. 6C, as will be discussed subsequently. TSVs 60B and 60C′ carry the same voltage, and are connected in parallel.

In accordance with some embodiments, the layout of the structure shown in FIG. 1B is identical to the layout of the structure shown in FIG. 1A, except that some TSVs in the structure shown in FIG. 1A are merged into the TSVs as shown in FIG. 1B, and the corresponding guard rings are also merged. Accordingly, the features surrounding, overlying, and underlying the TSVs in FIG. 1B are identical to the corresponding features in FIG. 1A.

FIGS. 6A, 6B, 6C, 6D, and 6E illustrate the TSVs that are capable of being merged have been merged. FIGS. 6A, 6B, 6C, 6D, and 6E correspond to FIGS. 3A, 3B, 3C, 3D, and 3E, respectively. The features are marked using legend. It is appreciated that due to the criteria as discussed above, some of the merged TSVs are electrically connected to, and may sometimes in physical contact with the same conductive features 34T. Accordingly, the neighboring TSVs connected to the same conductive features 34T may have different sizes and/or different shapes.

FIG. 6F illustrates the merged TSVs, with merging more TSVs as the highest priority. FIG. 6G illustrates the merged TSVs, with merging horizontally located TSVs as the highest priority. FIG. 6H illustrates the merged TSVs, with merging vertically located TSVs as the highest priority.

The merging scheme as shown in FIGS. 6A, 6B, 6C, 6D, 6E, 6F, 6G, and 6H may be performed for the same layout, and may be manufactured in the same wafer in any combination. Accordingly, the corresponding large TSVs and single TSVs as shown in these figures may be found in the same wafer and same device die in any combination.

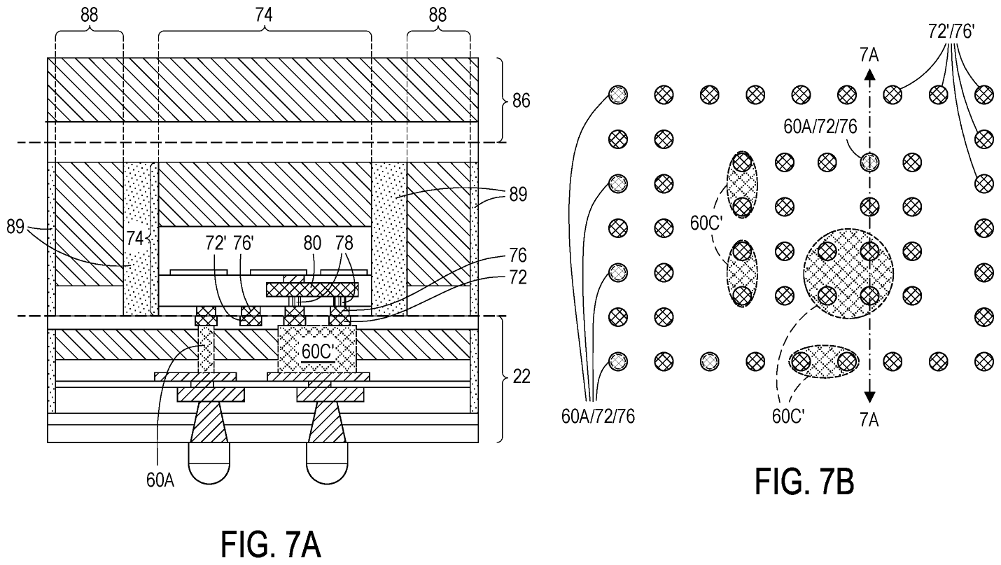

The merged TSVs and unmerged TSVs as discussed in accordance with the embodiments of the present application are manufactured on semiconductor wafers, which are sawed into discrete device dies and packaged in various type of packages. FIG. 7A schematically illustrates a cross-sectional view of a package incorporating the merged TSV in accordance with some embodiments. The package 86 includes a supporting silicon substrate, which is free from active devices and passive devices. The package 86 further includes dummy dies 88, which are formed of silicon, and may also be free from active devices and passive devices. Dummy dies 88 and a top device die 74 (also refer to FIGS. 1A and 6), which includes bond pads 76, dummy bond pads 76′, and metal line 80 are encapsulated in a gap-filling material 89. Device die 22 is underlying and bonding to device die 74 through bond pads 72 and dummy bond pads 72′. Unmerged TSV 60A and merged TSV 60C′ are also formed to connect to the bond pads 72 and 76.

The cross-sectional view as shown in FIG. 7A is obtained from the cross-section 7A-7A in FIG. 7B, which illustrates a top view of dummy bond pads 72′/76′, active bond pads 72/76, unmerged TSV 60A, and merged TSV 60C′. The circular patterns in the merged TSV 60C′ illustrate the shapes of the TSVs that otherwise will be formed if the TSVs are not merged.

The merged and the unmerged TSVs in accordance with the embodiments of the present disclosure may be formed in any of the via-first process, via-middle process, and via-last process. FIGS. 8, 9, and 10 illustrate a schematic process in the formation of TSVs through a via-first process. FIG. 8 illustrates the formation of via openings 60A″ and 60C″ extending into semiconductor substrate 24. The positions of the TSVs 60C and 60D that otherwise will be formed as illustrated. FIG. 9 illustrates the formation of TSVs 60A and 60C′, and the formation of a front-end of line (FEOL) structures such as integrated circuit devices 26 after the formation of TSVs 60A and 60C′. Back-end of line (BEOL) structures 34/36/38 including metal lines 34, vias 36, and dielectric layers 38 are then formed. FIG. 10 illustrates the bonding of another feature such as carrier 89 to the underlying device wafer 20.

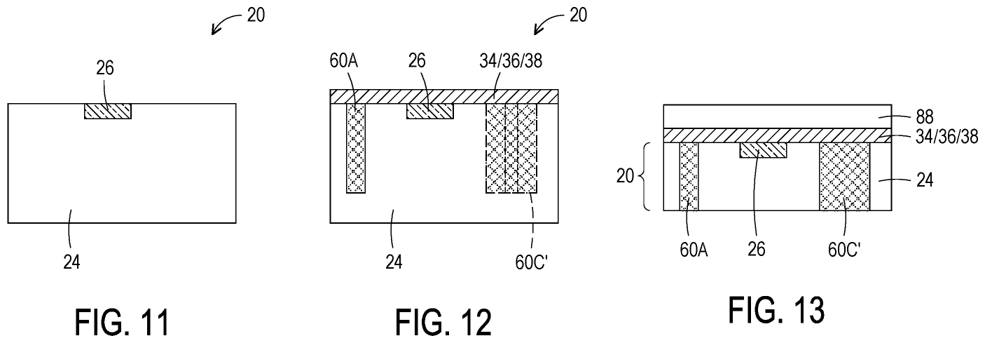

FIGS. 11, 12, and 13 illustrate the formation of vias through a via-middle process, in which TSVs 60A and 60C′ are formed after the formation of the FEOL structure 26, and before the BEOL structure 34/36/38.

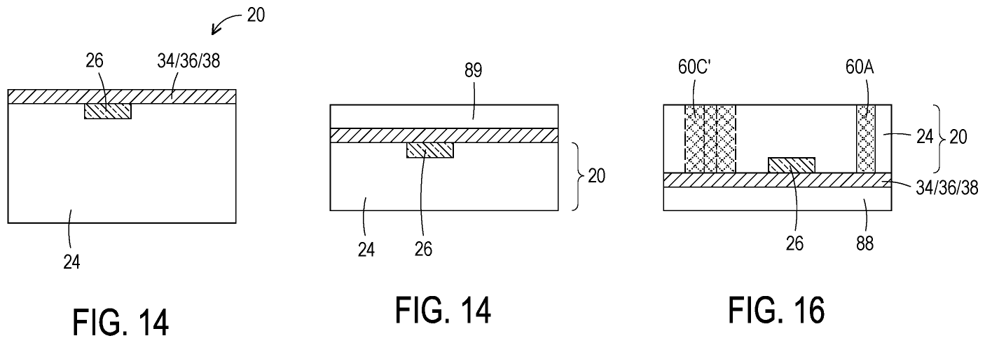

FIGS. 14, 15, and 16 illustrate the formation of vias through a via-last process, in which TSVs 60A and 60C′ are formed after the formation of the FEOL structure 26 and after the formation of the BEOL structure 34/36/38. TSVs 60A and 60C′ are formed from the backside of semiconductor substrate 24.

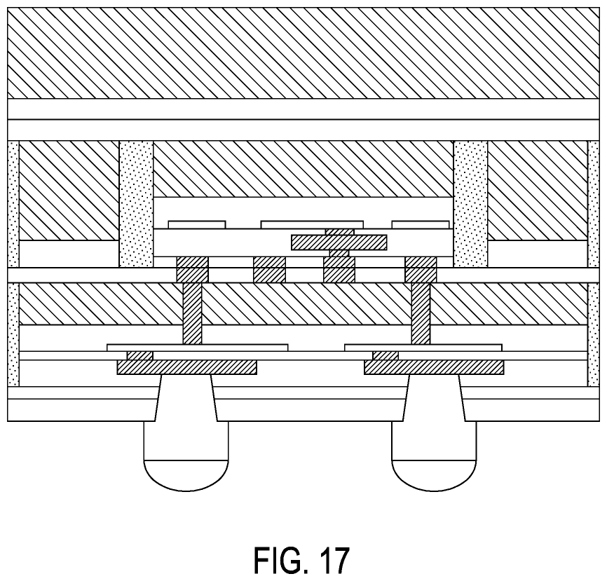

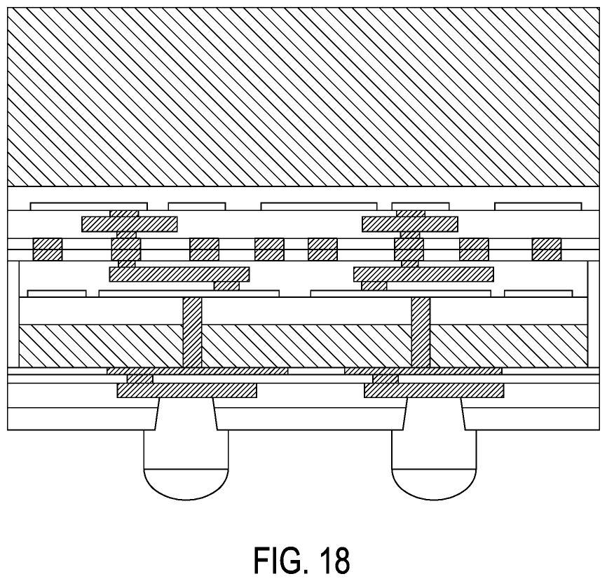

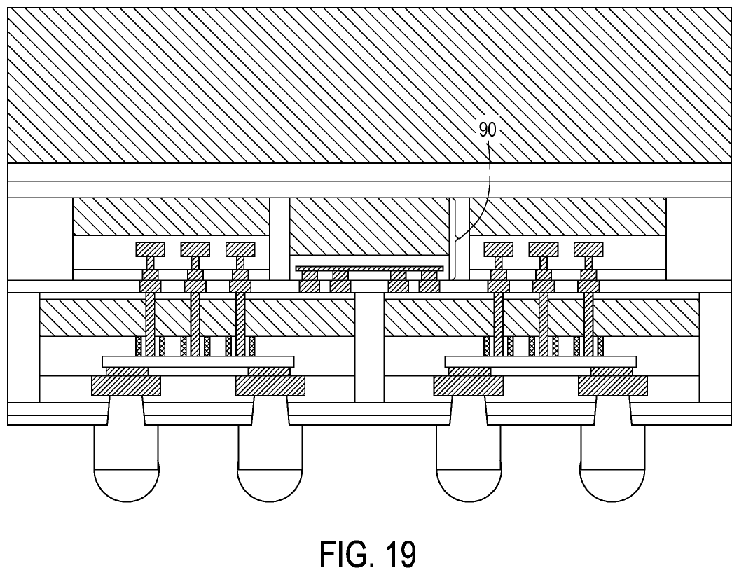

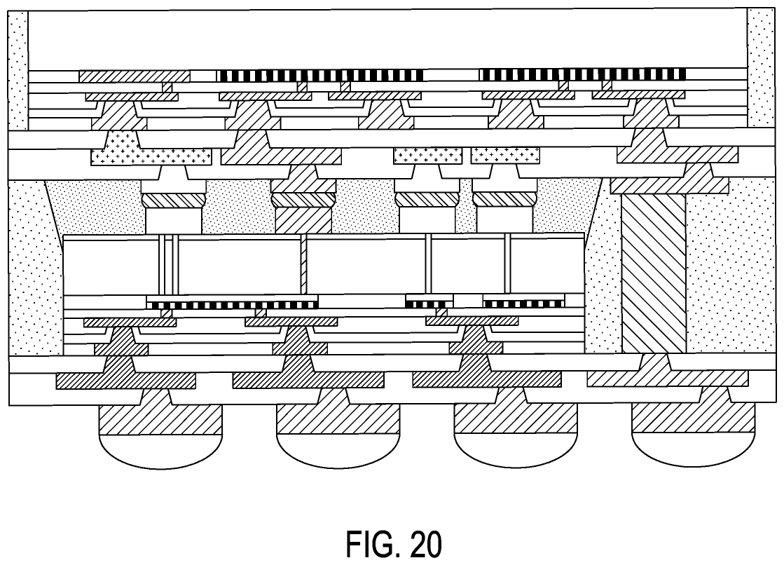

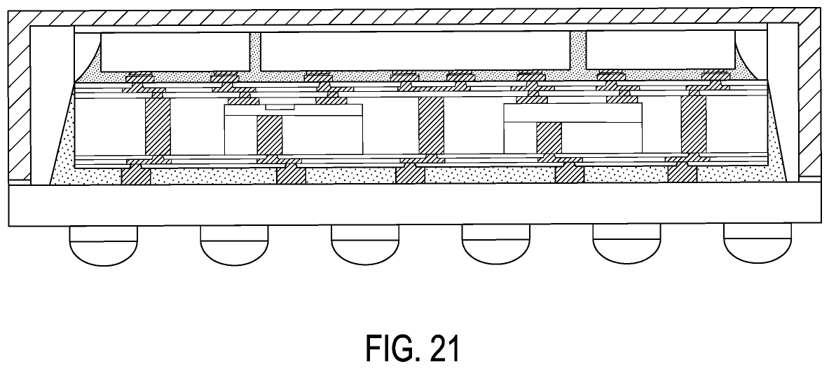

FIGS. 17 through 21 illustrate some example packages in which the merged and unmerged TSVs may be adopted. FIG. 17 illustrates a package similar to the package in FIG. 7A, which package includes a supporting substrate, dummy dies, a top die, and a bottom die. The top die is bonded to the bottom die through face-to-back bonding. FIG. 18 illustrates a package in which the top die is bonded to the bottom die through face-to-face bonding. FIG. 19 illustrates a package including a bridge die 90. FIG. 20 illustrates an Integrated Fan-Out (InFO) package. FIG. 21 illustrates a package including a plurality of types of package components bonding to an interposer, which is further bonded to an integrated fan-out package.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By merging some closely located TSVs, the resistance of the TSVs may be reduced without increasing the chip area occupied by the TSVs. The manufacturing cost is not increased. The occupied chip area may also be reduced when the resistance values of the TSVs are reduced, releasing some chip area for the formation of other circuits.

In accordance with some embodiments of the present disclosure, a method comprises finding a first plurality of through-silicon vias from a first layout of a wafer; finding a second plurality of through-silicon vias from the first plurality of through-silicon vias, wherein the second plurality of through-silicon vias are connected in parallel; and merging the second plurality of through-silicon vias into a large through-silicon via to generate a second layout of the wafer. In an embodiment, in the first layout, each of the second plurality of through-silicon vias is encircled by a guard ring, and wherein the method further comprises merging the guard rings that encircle the second plurality of through-silicon vias into a large guard ring that encircles the large through-silicon via.

In an embodiment, the large guard ring occupies a chip area same as a contour area of the guard rings that encircle the second plurality of through-silicon vias. In an embodiment, the method further comprises implementing the second layout through a manufacturing process to manufacture the wafer, wherein the manufacturing process comprises forming the large through-silicon via penetrating through a semiconductor substrate in the wafer. In an embodiment, the first plurality of through-silicon vias have a same shape and a same size, and the large through-silicon via has a same shape as, and is large than, one of the first plurality of through-silicon vias. In an embodiment, the first plurality of through-silicon vias have circular top-view shapes, and the large through-silicon via has an oval top-view shape.

In an embodiment, in the first layout, the second plurality of through-silicon vias are joined to a same metal pad. In an embodiment, the method further comprises finding a third plurality of through-silicon vias from the first plurality of through-silicon vias, wherein the second plurality of through-silicon vias are connected in parallel with the third plurality of through-silicon vias; and merging the third plurality of through-silicon vias into an additional large through-silicon via in the second layout of the wafer. In an embodiment, a first total count of the second plurality of through-silicon vias is equal to a second total count of the third plurality of through-silicon vias.

In an embodiment, a first total count of the second plurality of through-silicon vias is greater than a second total count of the third plurality of through-silicon vias. In an embodiment, the method further comprises implementing the second layout to manufacture the wafer, wherein in the wafer, the large through-silicon via and the additional large through-silicon via are in physical contact with a metal pad. In an embodiment, the method further comprises finding an additional through-silicon via from the first plurality of through-silicon vias, wherein in the second layout, the additional through-silicon via is physically separated from, and is connected in parallel with, the large through-silicon via.

In accordance with some embodiments of the present disclosure, a method comprises providing a first layout comprising a first plurality of through-vias; a second plurality of through-vias, wherein the first plurality of through-vias and the second plurality of through-vias have a same top-view size; generating a second layout, wherein the generating the second layout comprises merging the first plurality of through-vias to generate a large through-via in the second layout, and wherein the second plurality of through-vias remain to be discrete through-vias in the second layout; and manufacturing a wafer implementing the second layout.

In an embodiment, in the wafer, the first plurality of through-vias are joined to a same metal pad, and wherein the same metal pad has the same size and shape in the first layout and the second layout. In an embodiment, the generating the second layout further comprises merging guard rings encircling the first plurality of through-vias to form a large guard ring encircling the large through-via. In an embodiment, the large through-via has a greater top-view area than a total area of the first plurality of through-vias. In an embodiment, the large guard ring has a same top-view area as a contour area of the guard rings encircling the first plurality of through-vias.

In accordance with some embodiments of the present disclosure, a method comprises finding a first plurality of through-vias from a first layout of an integrated circuits, wherein in the first layout, the first plurality of through-vias are in contact with a metal pad; merging the first plurality of through-vias to form a large through-via and to generate a second layout; finding a second plurality of through-vias from the first layout, wherein in the first layout, the second plurality of through-vias are in contact with a plurality of metal pads, and wherein in the second layout, the second plurality of through-vias are discrete through-vias; and manufacturing the large through-vias and the second plurality of through-vias in a wafer.

In an embodiment, the first layout further comprises an additional through-via in contact with the metal pad, and wherein in the wafer, the additional through-via and the large through-via are separate through-vias that are connected in parallel. In an embodiment, the second plurality of through-vias are arranged as a row

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
finding a first plurality of through-silicon vias from a first layout of a wafer;
finding a second plurality of through-silicon vias from the first plurality of through-silicon vias, wherein the second plurality of through-silicon vias are connected in parallel; and
merging the second plurality of through-silicon vias into a large through-silicon via to generate a second layout of the wafer.

2. The method of claim 1, wherein in the first layout, each of the second plurality of through-silicon vias is encircled by a guard ring, and wherein the method further comprises merging the guard rings that encircle the second plurality of through-silicon vias into a large guard ring that encircles the large through-silicon via.

3. The method of claim 2, wherein the large guard ring occupies a chip area same as a contour area of the guard rings that encircle the second plurality of through-silicon vias.

4. The method of claim 1, further comprising:
implementing the second layout through a manufacturing process to manufacture the wafer, wherein the manufacturing process comprises forming the large through-silicon via penetrating through a semiconductor substrate in the wafer.

5. The method of claim 1, wherein the first plurality of through-silicon vias have a same shape and a same size, and the large through-silicon via has a same shape as, and is large than, one of the first plurality of through-silicon vias.

6. The method of claim 1, wherein the first plurality of through-silicon vias have circular top-view shapes, and the large through-silicon via has an oval top-view shape.

7. The method of claim 1, wherein in the first layout, the second plurality of through-silicon vias are joined to a same metal pad.

8. The method of claim 1, further comprising:
finding a third plurality of through-silicon vias from the first plurality of through-silicon vias, wherein the second plurality of through-silicon vias are connected in parallel with the third plurality of through-silicon vias; and
merging the third plurality of through-silicon vias into an additional large through-silicon via in the second layout of the wafer.

9. The method of claim 8, wherein a first total count of the second plurality of through-silicon vias is equal to a second total count of the third plurality of through-silicon vias.

10. The method of claim 8, wherein a first total count of the second plurality of through-silicon vias is greater than a second total count of the third plurality of through-silicon vias.

11. The method of claim 8 further comprising implementing the second layout to manufacture the wafer, wherein in the wafer, the large through-silicon via and the additional large through-silicon via are in physical contact with a metal pad.

12. The method of claim 1 further comprising:
finding an additional through-silicon via from the first plurality of through-silicon vias, wherein in the second layout, the additional through-silicon via is physically separated from, and is connected in parallel with, the large through-silicon via.

13. A method comprising:
providing a first layout comprising:
a first plurality of through-vias;
a second plurality of through-vias, wherein the first plurality of through-vias and the second plurality of through-vias have a same top-view size;
generating a second layout, wherein the generating the second layout comprises merging the first plurality of through-vias to generate a large through-via in the second layout, and wherein the second plurality of through-vias remain to be discrete through-vias in the second layout; and
manufacturing a wafer implementing the second layout.

14. The method of claim 13, wherein in the wafer, the first plurality of through-vias are joined to a same metal pad, and wherein the same metal pad has the same size and shape in the first layout and the second layout.

15. The method of claim 13, wherein the generating the second layout further comprises merging guard rings encircling the first plurality of through-vias to form a large guard ring encircling the large through-via.

16. The method of claim 15, wherein the large through-via has a greater top-view area than a total area of the first plurality of through-vias.

17. The method of claim 16, wherein the large guard ring has a same top-view area as a contour area of the guard rings encircling the first plurality of through-vias.

18. A method comprising:
finding a first plurality of through-vias from a first layout of an integrated circuits, wherein in the first layout, the first plurality of through-vias are in contact with a metal pad;
merging the first plurality of through-vias to form a large through-via and to generate a second layout;
finding a second plurality of through-vias from the first layout, wherein in the first layout, the second plurality of through-vias are in contact with a plurality of metal pads, and wherein in the second layout, the second plurality of through-vias are discrete through-vias; and
manufacturing the large through-vias and the second plurality of through-vias in a wafer.

19. The method of claim 18, wherein the first layout further comprises an additional through-via in contact with the metal pad, and wherein in the wafer, the additional through-via and the large through-via are separate through-vias that are connected in parallel.

20. The method of claim 18, wherein the second plurality of through-vias are arranged as a row.
